(19) United States
(12) Patent Application Publication
(10) Pub. No.: US 2014/0176215 A1
(43) Pub. Date: Jun. 26, 2014

(54) METHOD OF IMPLEMENTING CLOCK SKEW AND INTEGRATED CIRCUIT ADOPTING THE SAME

(71) Applicant: SAMSUNG ELECTRONICS CO., LTD., Gyeonggi-do (KR)

(72) Inventors: Suhail AHMED, Hwaseong-si (KR); Ahsan Chowdhury, Hwaseong-si (KR); Brian Millar, Hwaseong-si (KR)

(73) Assignee: Samsung Electronics Co., Ltd., Gyeonggi-do (KR)

(21) Appl. No.: 13/724,977

(22) Filed: Dec. 21, 2012

(51) Int. Cl. H03H 11/26

(52) U.S. Cl. CPC H03H 11/26
USPC 327/269

(57) ABSTRACT

To implement a clock skew in an integrated circuit, end-point circuits are grouped into a push group and a pull group based on target latencies of local clock signals respectively driving the end-point circuits. The push group is driven by slow clock gates, and the pull group is driven by fast clock gates. The slow clock gates are determined such that delays of output clock signals are aligned to a base latency. The fast clock gates are determined such that delays of output clock signals are aligned to a minimum pull latency smaller than the base latency. Buffer networks are disposed between the fast and slow clock gates and the end-point circuits such that the local clock signals have the target latencies, respectively.

### TECHNICAL FIELD

Exemplary embodiments relate generally to semiconductor integrated circuits, and more particularly, to a method of implementing a clock skew and an integrated circuit adopting the method.

### DISCUSSION OF THE RELATED ART

Demand for integrated circuits with reduced size and power consumption is increasing, and in particular, for use in mobile devices. The size and power consumption of an integrated circuit may be reduced by adjusting a clock skew between local clock signals applied to end point circuits in the integrated circuit.

### SUMMARY

In a method of implementing a clock skew in an integrated circuit according to an exemplary embodiment of the present invention, end-point circuits are grouped into a push group and a pull group based on target latencies of local clock signals respectively driving the end-point circuits. The end-point circuits in the push group are driven by one or more slow clock gates, and the end-point circuits in the pull group are driven by one or more fast clock gates. The slow clock gates are determined such that delays of output clock signals from the slow clock gates are aligned to a base latency. The fast clock gates are determined such that delays of output clock signals from the fast clock gates are aligned to a minimum pull latency smaller than the base latency. One or more buffer networks are disposed between the fast and slow clock gates and the end-point circuits such that the local clock signals have the target latencies, respectively.

Grouping the end-point circuits may include establishing an initial placement design of the integrated circuit such that the end-point circuits are driven by the slow clock gates, when a predetermined number of the end-point circuits driven by a first slow clock gate of the slow clock gates in the initial placement design are included in the pull group, separating the predetermined number of the end-point circuits from the first slow clock gate and disposing a first fast clock gate to drive the predetermined number of the end-point circuits, and when all of the end-point circuits driven by the first slow clock gate in the initial placement design are included in the pull group, replacing the first slow clock gate with the first fast clock gates to drive all of the end-point circuits.

Grouping the end-point circuits may further include merging the slow clock gates with each other when the slow clock gates have the same input signal and are disposed adjacent to each other, and merging the fast clock gates with each other when the fast clock gates have the same input signal and are disposed adjacent to each other.

The base latency may be a sum of a slow clock gate latency that occurs before a predetermined slow clock gate of the slow clock gates, a slow clock gate delay that occurs in the predetermined slow clock gate, and a first net delay threshold that is an upper limit of a delay that occurs from the predetermined slow clock gate to a predetermined end-point circuit of the end-point circuits. The minimum pull latency may be a sum of a fast clock gate latency that occurs before a predetermined fast clock gate of the fast clock gates, a fast clock gate delay that occurs in the predetermined fast clock gate, and a second net delay threshold that is an upper limit of a delay that occurs from the predetermined fast clock gate to another predetermined end-point circuit of the end-point circuits.

The slow clock gate latency and the fast clock gate latency may be set to constant values by driving the slow and fast clock gates using a clock distribution network including a clock mesh, and the slow clock gate delay, the fast clock gate delay and the first and second net delay thresholds may be set to constant values based on an entire occupation area of the slow and fast clock gates.

Determining the slow clock gates may include, based on an input transition and a driving load of the first slow clock gate, selecting a clock gate from a clock gate library such that the selected clock gate has a delay closest to the constant value of the slow clock gate delay and setting a size of the first slow clock gate to a size of the selected clock gate.

Determining the slow clock gates may further include, when the clock gate library does not include the clock gate having the delay closest to the constant value of the slow clock gate delay with respect to the first slow clock gate, dividing the end-point circuits driven by the first slow clock gate into two or more groups and replacing the first slow clock gate with two or more other slow clock gates configured to respectively drive the two or more groups of the end-point circuits.

Determining the slow clock gates may further include computing a current slow clock gate delay and a current net delay with respect to the first slow clock gate; when a sum of the current slow clock gate delay and the current net delay is greater than a sum of the constant value of the slow clock gate delay and the constant value of the net delay threshold or when the current net delay is greater than the constant value of the net delay threshold, dividing the end-point circuits driven by the first slow clock gate into two or more groups and replacing the first slow clock gate with two or more slow clock gates configured to respectively drive the two or more groups of the end-point circuits.

Determining the slow clock gates may further include computing a current slow clock gate delay and a current net delay with respect to the first slow clock gate and adding a dummy load to an output node of the first slow clock gate such that a sum of the current slow clock gate delay and the current net delay is equal or substantially equal to a sum of the constant value of the slow clock gate delay and the constant value of the net delay threshold.

Determining the fast clock gates may include, based on an input transition and a driving load of the first fast clock gate, selecting a clock gate from a clock gate library such that the selected clock gate has a delay closest to the constant value of the fast clock gate delay and setting a size of the first fast clock gate to a size of the selected clock gate.

Determining the fast clock gates may further include, when the clock gate library does not include the clock gate having the delay closest to the constant value of the fast clock gate delay with respect to the first fast clock gate, dividing the end-point circuits driven by the first fast clock gate into two or more groups, and replacing the first fast clock gate with two or more other fast clock gates configured to respectively drive the two or more groups of the end-point circuits.

Determining the fast clock gates may further include computing a current fast clock gate delay and a current net delay with respect to the first fast clock gate, when a sum of the current fast clock gate delay and the current net delay is greater than a sum of the constant value of the fast clock gate delay and the constant value of the net delay threshold or when the current net delay is greater than the constant value of the net delay threshold, dividing the end-point circuits driven by the first fast clock gate into two or more groups, and replacing the first fast clock gate with two or more other fast clock gates configured to respectively drive the two or more groups of the end-point circuits.

Determining the fast clock gates may further include computing a current fast clock gate delay and a current net delay with respect to the first fast clock gate and adding a dummy load to an output node of the first fast clock gate such that a sum of the current fast clock gate delay and the current net delay is equal or substantially equal to a sum of the constant value of the fast clock gate delay and the constant value of the net delay threshold.

Disposing the buffer networks may include, with respect to one of the end-point circuits driven by one of the slow clock gates or one of the fast clock gates, computing a push amount corresponding to a difference between a corresponding target latency of the target latencies and the base latency or a difference between the corresponding target latency and the minimum pull latency; selecting a buffer from a buffer library such that the selected buffer has a delay closest to the push amount; and disposing the selected buffer between the one end-point circuit and the one slow clock gate or between the one end-point circuit and the one fast slow clock gate.

The method may further include, after determining the slow clock gates and the fast clock gates, with respect to the end-point circuits driven by one of the slow clock gates or one of the fast clock gates, computing push amounts corresponding to differences between corresponding target latencies of the target latencies and the base latency or differences between the corresponding target latencies and the minimum pull latency; selecting a buffer from a buffer library such that the selected buffer has a delay closest to a minimum push amount of the push amounts; and disposing the selected buffer on a common path between the end-point circuits and the one slow clock gate or between the end-point circuits and the one fast slow clock gate.

The method may further include, after determining the slow clock gates and the fast clock gates, with respect to the end-point circuits driven by one of the slow clock gates or one of the fast clock gates, computing push amounts corresponding to differences between corresponding target latencies of the target latencies and the base latency or differences between the corresponding target latencies and the minimum pull latency; selecting a clock gate from a clock gate library such that the selected clock gate has a delay closest to a sum of a minimum push amount of the push amounts and the base latency or a sum of the minimum push amount and the minimum pull latency; and setting a size of the one slow clock gate or the one fast clock gate to a size of the selected clock gate.

According to an exemplary embodiment of the present invention, an integrated circuit a clock distribution network, one or more slow clock gates, one or more fast clock gates, one or more buffer networks and end-point circuits.

The clock distribution network includes a clock mesh configured to provide one or distributed clock signals. The slow clock gates receive the distributed clock signals to output clock signals having delays aligned to a base latency. The fast clock gates receive the distributed clock signals to output clock signals having delays aligned to a minimum pull latency smaller than the base latency. The buffer networks delay the clock signals from the slow clock gates and the fast clock gates to provide local clock signals having target latencies, respectively. The end-point circuits receive the local clock signals, respectively, from the slow clock gates, the fast clock gates or the buffer networks.

According to an exemplary embodiment of the present invention, a method of implementing a clock skew in an integrated circuit includes providing a basic placement design for the integrated circuit. The basic placement design includes a list of end-point circuits, a library of clock gates, and a library of buffers, establishing a clock distribution network based on the basic placement design to provide an initial placement design. The clock distribution network is connected to the end-point circuits via the clock gates, performing skew scheduling on the basic placement design to provide target latencies of local clock signals from the clock gates, and implementing the clock skew by disposing at least one of the buffers between the clock gates and the end-point circuits based on the initial placement design and the target latencies.

The method may further include correcting the basic placement design or the clock distribution network based on information generated when the clock skew is implemented.

The clock gates may include a slow clock gate and a fast clock gate. A delay of an output clock signal from the slow clock gate is aligned to a base latency, and a delay of an output clock signal of from the fast clock gate is aligned to a minimum pull latency smaller than the base latency.

### BRIEF DESCRIPTION OF THE DRAWINGS

The above and other features of the present invention will be more clearly understood by describing in detail exemplary embodiments thereof in conjunction with the accompanying drawings in which:

FIG. 1 is a flowchart illustrating a method of implementing clock skew in an integrated circuit according to an exemplary embodiment of the present invention;

FIG. 2 is a diagram illustrating an initial placement design of an integrated circuit before the skew implementation method is applied;

FIG. 3 is a diagram illustrating a placement design of an integrated circuit after the skew implementation method of FIG. 1 is applied;

FIG. 4 is a diagram for describing a method of designing an integrated circuit according to an exemplary embodiment of the present invention;

FIG. 5 is a flowchart illustrating an exemplary process of grouping the end-point circuits included in the method of FIG. 1;

FIG. 6 is a diagram illustrating a placement design of an integrated circuit after the process of FIG. 5 is performed;

FIG. 7 is a diagram illustrating a base latency and a minimum pull latency that are used in the method of FIG. 1:

FIG. 8 is a diagram illustrating an example of a clock distribution network;

FIG. 9 is a diagram for described a clock gate latency in the clock distribution network of FIG. 8;

FIG. 10 is a flowchart illustrating an exemplary process of determining the slow clock gates included in the method of FIG. 1;

FIG. 11 is a diagram illustrating a placement design of an integrated circuit after the process of FIG. 10 is performed;

FIG. 12 is a flowchart illustrating an exemplary process of determining the fast clock gates included in the method of FIG. 1;

FIG. 13 is a diagram illustrating a placement design of an integrated circuit after the process of FIG. 12 is performed;

FIG. 14 is a flowchart illustrating an exemplary process of disposing the buffer networks included in the method of FIG. 1;

FIG. 15 is a flowchart illustrating a method of implementing clock skew in an integrated circuit according to an exemplary embodiment of the present invention;

FIG. 16 is a diagram illustrating a placement design of an integrated circuit after which the skew implementation method of FIG. 15 is applied;

FIGS. 17A, 17B and 17C are diagrams illustrating clock transfer paths for describing methods of implementing clock skew according to exemplary embodiments of the present invention;

FIG. 18 is a block diagram illustrating a computing system according to an exemplary embodiment of the present invention; and

FIG. 19 is a block diagram illustrating an interface used in the computing system of FIG. 18 according to an exemplary embodiment of the present invention.

### DETAILED DESCRIPTION OF THE EMBODIMENTS

Various exemplary embodiments will be hereinafter described in more detail with reference to the accompanying drawings. The present inventive concept may, however, be embodied in many different forms and should not be construed as limited to the exemplary embodiments set forth herein. The same numerals may refer to the same or like elements throughout the drawings and the specification.

It will be understood that when an element is referred to as being “on”, “connected to” or “coupled to” another element, it can be directly on, connected or coupled to the other element or intervening elements may be present. As used herein, the singular forms “a,” “an” and “the” are intended to include the plural forms as well, unless the context clearly indicates otherwise.

As will be appreciated by one skilled in the art, embodiments of the present invention may be embodied as a system, method, computer program product, or a computer program product embodied in one or more computer readable medium(s) having computer readable program code embodied thereon. The computer readable program code may be provided to a processor of a general purpose computer, special purpose computer, or other programmable data processing apparatus. The computer readable medium may be a computer readable signal medium or a computer readable storage medium. The computer readable storage medium may be any tangible medium that can contain, or store a program for use by or in connection with an instruction execution system, apparatus, or device.

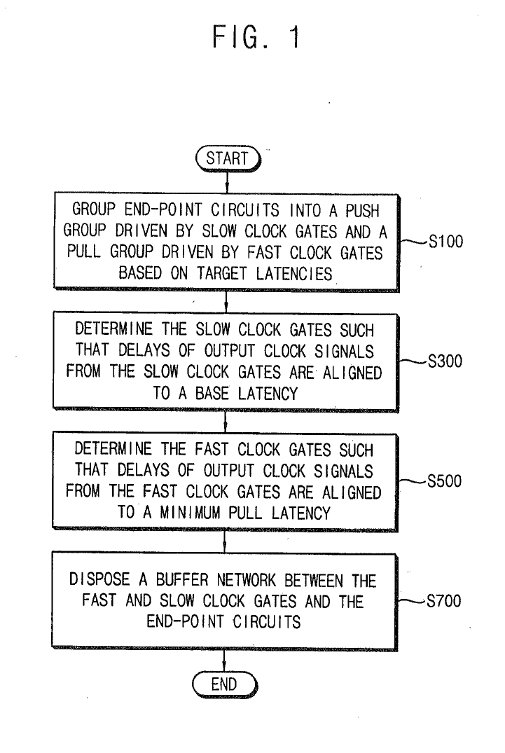

FIG. 1 is a flowchart illustrating a method of implementing clock skew in an integrated circuit according to an exemplary embodiment of the present invention.

Referring to FIG. 1, end-point circuits (EPCs) are grouped into a push group and a pull group based on target latencies of local clock signals (S100). The local clock signals are clock signals that are directly applied to respective clock input terminals of the EPCs. The EPCs in the push group are driven by one or more slow clock gates (SCGs), and the EPCs in the pull group are driven by one or more fast clock gates (FCGs). The EPC may be an arbitrary circuit driven by the local clock signal. The EPC may include at least one flip-flop, or at least one latch. Such grouping of the EPCs may be performed based on target latencies or latency constraints of the local clock signals. As will be described below, the push group has the target latencies greater than or equal to a base latency (BLAT) corresponding to zero-skew, and the pull group has the target latencies smaller than the BLAT and greater than or equal to a minimum pull latency (MPLAT).

The SCG is a clock gate having a relatively large delay, and the FCG is a clock gate having a relatively small delay. The delay of the clock gate is generally in inverse proportion to a size of the clock gate. Thus, the clock gate of the larger size may have the smaller delay and the clock gate of the smaller size may have the greater delay. The SCGs and FCGs may be integrated clock gates (ICGs) that are formed using a semiconductor substrate. In an exemplary embodiment, the SCG may be a pulsed ICG and the FCG may be a non-pulsed ICG.

After the EPCs are grouped, the SCGs are determined or optimized such that delays of output clock signals from the SCGs are aligned to the BLAT (S300), and the FCGs are determined or optimized such that delays of output clock signals from the FCGs are aligned to the MPLAT smaller than the BLAT (S500). For example, determination of the SCGs may include determining one or more characteristics, e.g., size, of the SCGs.

Even though FIG. 1 illustrates that the SCGs are determined and then the FCGs are determined, the FCGs may be determined before the SCGs are determined or the SCGs and the FCGs are determined in parallel, e.g., at the same time. For example, determination of the FCGs may include determining one or more characteristics, e.g., size, of the FCGs.

After the SCGs and the FCGs are determined or optimized, a buffer network is disposed between the fast and slow clock gates and the end-point circuits such that all of the local clock signals have the respective target latencies (S700).

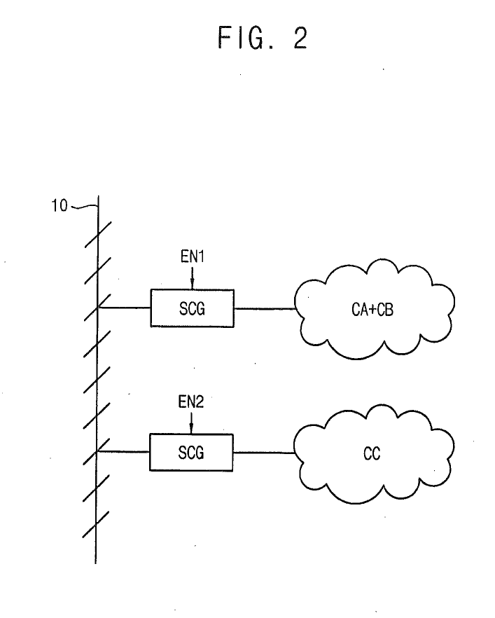

FIG. 2 is a diagram illustrating an initial placement design of an integrated circuit before the skew implementation method is applied.

Referring to FIG. 2, an initial placement design of an integrated circuit includes a clock distribution network 10, SCGs and end-point clusters CA, CB and CC. Each end-point cluster may include one or more EPCs. The clock distribution network 10 drives the SCGs and the SCGs drive the end-point clusters CA, CB and CC. For convenience of illustration and description, FIG. 2 illustrates two SCGs that may be enabled by two input signals EN1 and EN2, respectively, and the end-point clusters CA, CB and CC driven by the two SCGs. However, according to an embodiment of the present invention, the initial placement design may include three or more SCGs.

In the initial placement design, each of the EPCs, e.g., all end-point clusters CA, CB and CC are driven by the typical SCGs. The typical SCGs have a non-optimized size for the target latencies or the latency constraints of the local clock signals.

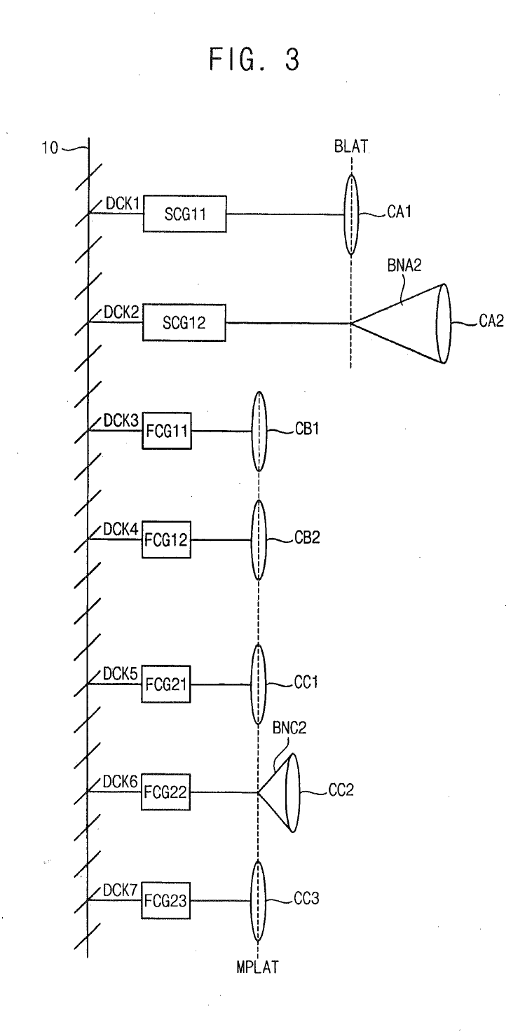

FIG. 3 is a diagram illustrating a placement design of an integrated circuit after the skew implementation method of FIG. 1 is applied.

Referring to FIG. 3, a placement design of an integrated circuit includes a clock distribution network 10, one or more slow clock gates SCG11 and SCG12, one or more fast clock gates FCG11, FCG12, FCG21, FCG22 and FCG23, one or more buffer networks BNA2 and BNC2, and end-point clusters CA1, CA2, CB1, CB2, CC1, CC2 and CC3. Each end-point cluster includes one or more EPCs.

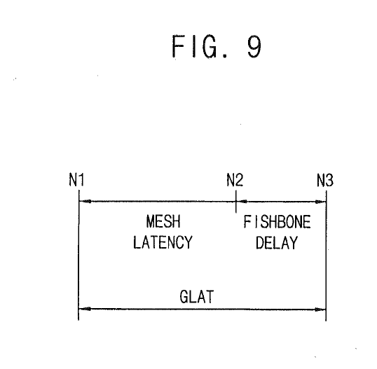

As will be described below with reference to FIG. 8, the clock distribution network provides distributed clock signals (DCKs) for driving the slow clock gates and the fast clock gates. The clock distribution network 10 may include an H-tree and a clock mesh.

The slow clock gates SCG11 and SCG12 receive the distributed clock signals DCK1 and DCK2 and output clock signals having delays aligned to the BLAT. The fast clock gates FCG11, FCG12, FCG21, FCG22 and FCG23 receive the distributed clock signals DCK3, DCK4, DCK5, DCK6 and DCK7 and output clock signals having delays aligned to the MPLAT smaller than the BLAT.

The buffer networks BNA2 and BNC2 delay the corresponding clock signals DCK2 and DCK6 from the slow clock gate SCG12 and the fast clock gates FCG22 and provide the local clock signals having the target latencies, respectively.

The end-point circuits in the end-point clusters CA1, CA2, CB1, CB2, CC1, CC2 and CC3 receive the local clock signals, respectively, from the slow clock gates, the fast clock gates or the buffer networks.

While FIG. 3 illustrates the relative delays or latencies of the clock signals, FIG. 3 does not necessarily represent the physical sizes of the elements or the physical distances between the elements.

A conventional method for implementing useful skew is based on skew selecting means provided in the clock drivers or the clock gates. For example, a plurality of the clock drivers/gates that have different amounts of skew or programmable amounts of skew are provided in the same or substantially the same footprint. In this example, the clock drivers/gates are sized to correspond to the biggest useful skew amount, and thus, occupation area and power consumption increase. Another conventional approach is to implement useful skew as part of clock tree synthesis (CTS). However, such an implementation is vulnerable to on-chip variation (OCV) and is not suitable for designs of high-performance devices.

In the method of implementing clock skew in the integrated circuit according to an exemplary embodiment, the number and the sizes of the clock gates are optimized and then the buffer networks are inserted between the optimized clock gates and the end-point circuits. Thus, the method is suitable for designs of high performance integrated circuits, such as processors, or integrated circuits, and may be robust to OCV. In addition, the occupation area and the power consumption of the integrated circuit may be reduced by optimizing the clock gates and the buffers.

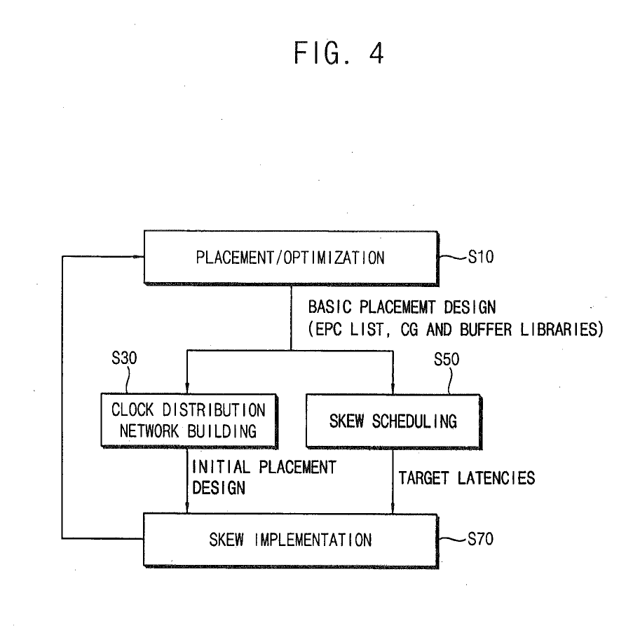

FIG. 4 is a diagram illustrating a method of designing an integrated circuit according to an exemplary embodiment.

Referring to FIG. 4, placement and optimization may be performed (S10) to thus provide a basic placement design of an integrated circuit. The basic placement design may include an end-point list, a clock gate library, a buffer library, etc.

Based on the basic placement design, the clock distribution network may be built (S30) to thus provide an initial placement design. As described above with reference to FIG. 2, in the initial placement design, all of the EPCs are driven by SCGs, and the SCGs have the non-optimized sizes for the target latencies or the latency constraints of the local clock signals that are respectively provided to the clock inputs of the EPCs.

Skew scheduling may be performed (S50) based on the basic placement design to thus provide the target latencies of the local clock signals. Such skew scheduling may be performed using a utility or tool.

Based on the initial placement design and the target latencies, skew implementation may be performed (S70) as described above with reference to FIGS. 1, 2 and 3. The intermediate and/or final results of the skew implementation may be fed back to thus modify the basic placement design and/or the clock distribution network.

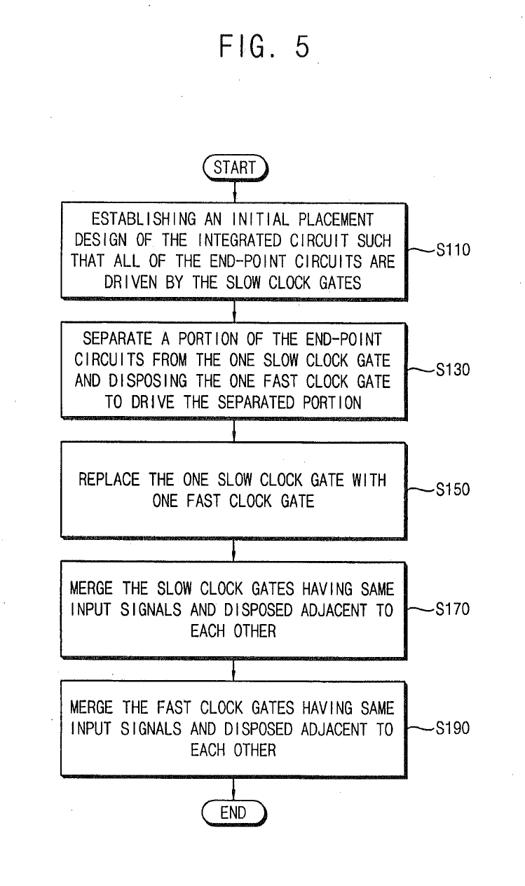

FIG. 5 is a flowchart illustrating an exemplary process of grouping the end-point circuits included in the method of FIG. 1.

Referring to FIG. 5, the initial placement design of the device is established such that all of the EPCs are driven by the SCGs (S110). The initial placement design may be established by establishing the basic placement design and then the clock distribution network as illustrated in FIG. 4.

When one or more of the EPCs driven by one SOC in the initial placement design are included in the pull group, the EPCs are separated from the one SCG and one FCG is disposed to drive the separated EPCs (S130).

When all of the EPCs driven by one SCG in the initial placement design are included in the pull group, the one SCG is replaced or swapped with one FCG to drive all of the EPCs (S150).

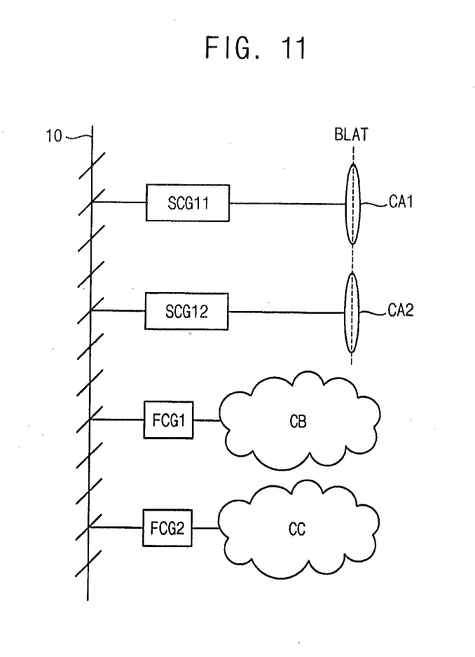

Two or more SCGs that have the same or substantially the same input signals and are disposed adjacent to each other are merged with each other (S170), and two or more FCGs that have the same or substantially the same input signals and are disposed adjacent to each other may be merged with each other (S190). The input signals may be enable signals EN1 and EN2 of the clock gates. The initial placement in FIG. 2 may represent a placement design obtained after such merging processes are performed. The merged clock gates may be further optimized through cloning processes as will be described below with reference to FIGS. 10, 11, 12 and 13.

According to an exemplary embodiment of the present invention, the processes S110, S130, S150, S170 and S190 may be performed in an arbitrary order and at least two processes may be performed in parallel, e.g., at the same time.

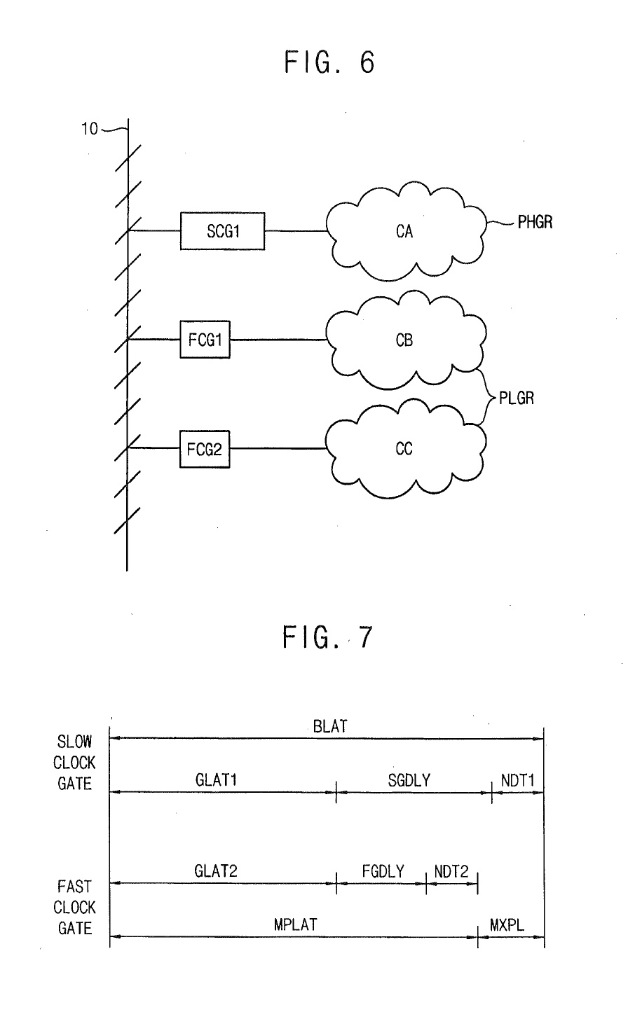

FIG. 6 is a diagram illustrating a placement design of an integrated circuit after the process of FIG. 5 is performed.

Referring to FIGS. 2, 5 and 6, when one (e.g., CB) of EPCs (CA and CB) driven by one SOC in the initial placement design is included in the pull group (PLGR), the EPC (e.g., CB) is separated from the one SCG, and one FCG is disposed to drive the separated EPC (e.g., CB). Thus, one end-point cluster CA+CB, which is driven by one SCG in FIG. 2, is divided into one end-point cluster CA and one end-point cluster CB, which are driven by the SCG1 and the FCG1, respectively, as shown in FIG. 6. The cluster CA belongs to the push group PSGR, and the cluster CB belongs to the pull group PLGR.

When all of the EPCs CC driven by the one SCG in the initial placement design are included in the pull group PLGR, one SCG is replaced or swapped with one FCG2 to drive all of the EPCs CC (S150). Thus, the end-point cluster CC, which is driven by the one SCG in FIG. 2, is replaced with the end-point cluster CC belonging to the pull group PLGR, which is driven by the one FCG2.

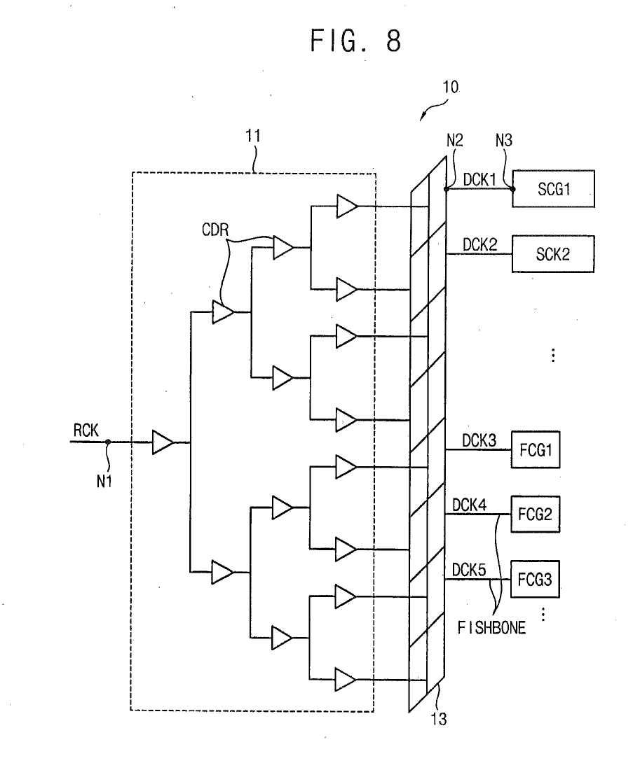

FIG. 7 is a diagram illustrating a base latency and a minimum pull latency that are used in the method of FIG. 1.

Referring to FIG. 7, the base latency BLAT may be set to a sum of a slow clock gate latency GLAT1, a slow clock gate delay SGDLY and a net delay threshold NDT1. The slow clock gate latency GLAT1 indicates a delay that occurs before the SCG, the slow clock gate delay SGDLY indicates a delay that occurs in the SCG, and the net delay threshold NDT1 indicates an upper limit of a delay that occurs from the SCG to the EPC.

The minimum pull latency MPLAT may be set to a sum of a fast clock gate latency GLAT2, a fast clock gate delay FGDLY and a net delay threshold NDT2. The fast clock gate latency GLAT2 indicates a delay that occurs before the FCG, the fast clock gate delay FGDLY indicates a delay that occurs in the FCG, and the net delay threshold NDT2 indicates an upper limit of a delay that occurs from the FCG to the EPC.

A difference MXPL between the BLAT and the MPLAT corresponds to a maximum pull amount. The difference MXPL corresponds to an amount of delay reduction when the SCG is swapped with the FCG.

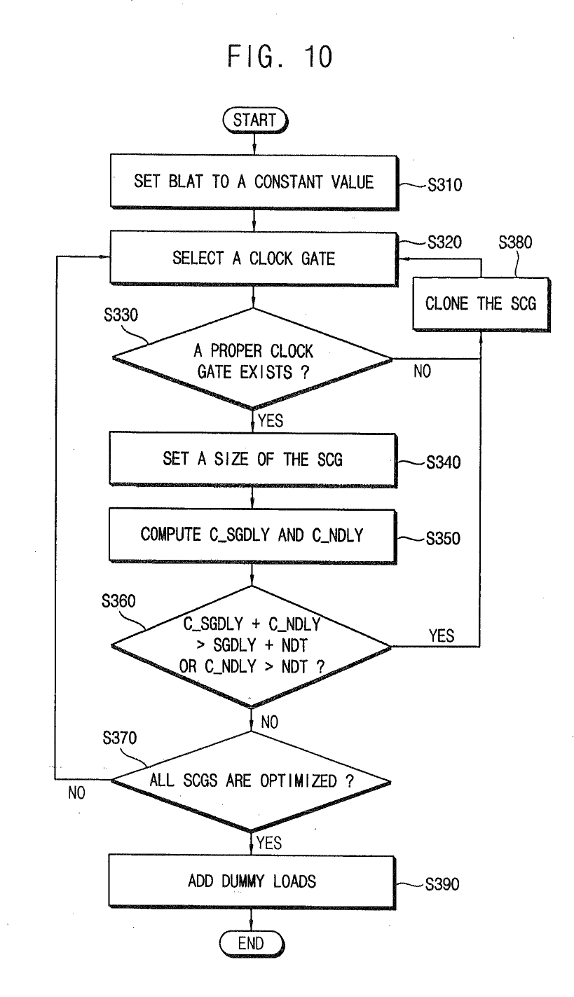

FIG. 8 is a diagram illustrating an example of a clock distribution network, and FIG. 9 is a diagram illustrating a clock gate latency in the clock distribution network of FIG. 8.

Referring to FIG. 8, a clock distribution network 10 may include an H-tree 11 and a clock mesh 13. The H-tree 11 may include a plurality of clock drivers CDRs that are disposed symmetrically. The H-tree 11 distributes a root clock signal RCK, which is applied to an input node, and drives multiple points on the clock mesh 13. The clock mesh 13 provides distributed clock signals DCK1 through DCK5 at output nodes N2. The slow clock gates SCG1 and SCG 2 and the fast clock gates FCG1, FCG2 and FCG3 are coupled to the clock mesh 13 through the branch lines or the fishbone and receive the distributed clock signals DCK1 through DCK5, respectively.

Through such clock distribution network 10, the distributed clock signals with substantially the same delay may be provided to the clock gates.

Referring to FIG. 9, a gate latency GLAT may be represented by a sum of a mesh latency and a fishbone delay. The mesh latency corresponds to a delay from a node N1, to which the root clock signal RCK is applied, to an output node N2 of the clock mesh 13. The fishbone delay corresponds to a delay from the output node N2 of the clock mesh 13 to an input node N3 of the clock gate.

With respect to the respective clock gates, the mesh latencies and the fishbone delays may be slightly different from each other. In general, the fishbone delays are very small compared with the mesh latency and thus the fishbone delay may be neglected. The deviations of the mesh latencies may be minimized using the clock distribution network as illustrated in FIG. 8. For example, the clock distribution network 10 may be implemented such that the gate latency GLAT is set to 300 ps (pico second) and a mesh skew, e.g., a skew between the distributed clock signals applied to the input nodes of the clock signals may be smaller than 10 ps. In this case, the gate latency GLAT may be set to a constant value of 300 ps.

As such, the slow clock gate latency GLAT1 and the fast clock gate latency GLAT described above in connection with FIG. 7 may be set to constant values by driving the SCGs and the FCGs using the clock distribution network 10 including the clock mesh 13. When the SCGs and the FCGs are driven by the same clock mesh, the slow clock gate latency GLAT1 and the fast clock gate latency GLAT may be set to the same constant value that is the gate latency GLAT.

The slow clock gate delay SGDLY and the net delay threshold NDT1 described above in connection with FIG. 7 may be set to predetermined constant values, respectively. The base latency BLAT may be minimized by setting the smaller values as the slow clock gate delay SGDLY and the net delay threshold NDT1. However, the smaller values of the slow clock gate delay SGDLY and the net delay threshold NDT1 may result in an increase in the number of the SCGs through a cloning process that is described below, and thus the entire occupation area of the SCGs may be increased. Accordingly, considering the entire occupation area of the SCGs, the slow clock gate delay SGDLY and the net delay threshold NDT1 may be set to values, which may be determined empirically.

In the same or substantially the same way, the fast clock gate delay FGDLY and the net delay threshold NDT2 described above in connection with FIG. 7 may be set to predetermined constant values, respectively. The minimum pull latency MPLAT may be minimized by setting the smaller values as the fast clock gate delay FGDLY and the net delay threshold NDT2. However, the smaller values of the fast clock gate delay FGDLY and the net delay threshold NDT2 may result in an increase in the number of the SCGs through a cloning process to be described below, and thus the entire occupation area of the FCGs may be increased. Accordingly, considering the entire occupation area of the FCGs, the fast clock gate delay FGDLY and the net delay threshold NDT2 may be set to values, which may be determined empirically.

For example, when designing a processor having an operational clock of 1.37 GHz, the clock cyclic period is about 729 ps. For purposes of description, the clock distribution network 10 of FIG. 8 is implemented such that the slow clock gate latency GLAT1 and the fast clock gate latency GLAT2 are about 300 ps. In this case, the slow clock gate delay SGDLY may be set to a constant value of 120 ps, and the net delay threshold NDT1 may be set to a constant value of 15 ps. Thus, the base latency BLAT may be set to a constant value of 435 ps (300+120+15). The fast clock gate delay FGDLY may be set to a constant value of 60 ps, and the net delay threshold NDT2 may be set to a constant value of 15 ps. Thus, the minimum pull latency MPLAT may be set to a constant value of 375 ps (300+60+15).

Hereinafter, processes of determining SCGs and FCGs are described with reference to FIGS. 10 through 13 to optimize the numbers and the sizes of the SCGs and the FCGs.

FIG. 10 is a flowchart illustrating an exemplary process of determining the slow clock gates included in the method of FIG. 1.

Referring to FIG. 10, the base latency BLAT is set to a constant value (S310). As described above with reference to FIGS. 7, 8 and 9, the constant base latency BLAT may be determined by setting the slow clock gate latency GLAT1, the slow clock gate delay SGDLY and the net delay threshold NDT1 to predetermined constant values, respectively.

Based on the input transition and the driving load with respect to one SCG, a clock gate is selected from the above-mentioned clock gate library (S320) such that the selected clock gate has a delay closest to the constant slow clock gate delay SGDLY.

When the clock gate library includes the clock gate having the delay closest to the constant slow clock gate delay SGDLY with respect to the one SCG (S330: YES), a size of the one SCG is set to a size of the selected clock gate (S340).

When the clock gate library does not include the clock gate having the delay closest to the constant slow clock gate delay SGDLY with respect to the one SCG (S330: NO), the one SCG is cloned into two or more SCGs (S380). The cloning process may be performed by dividing the EPCs driven by the one SCG into two or more groups, and then disposing two or more SCGs, which replace the one SCG, to drive the two or more groups, respectively. The size optimizing processes (S320, S330 and S340) may be repeated with respect to each of the cloned SCGs.

With respect to one size-set SCG, a current slow clock gate delay C_SGDLY and a current net delay C_NDLY are computed (S340).

When a sum C_SGDLY+C_NDLY of the current slow clock gate delay C_SGDLY and the current net delay C_NDLY is greater than a sum SGDLY+NDT of the constant slow clock gate delay SGDLY and the constant net delay threshold NDT or when the current net delay C_NDLY is greater than the constant net delay threshold NDT (S360: YES), the one SCG is cloned into the two or more SCGs (S380) as described above.

Until the size optimization is complete with respect to all SCGs (S370: NO), the above-described size-determining and cloning processes are repeated.

When the sizes optimization is complete with respect to all SCGs (S370: YES), dummy loads may be added to output nodes of the SCGs, respectively (S390). The respective dummy load may be added to an output node of the one size-set SCG such that the sum C_SGDLY+C_NDLY of the current slow clock gate delay C_SGDLY and the current net delay C_NDLY is equal or substantially equal to the sum SGDLY+NDT of the constant slow clock gate delay SGDLY and the constant net delay threshold NDT. The current slow clock gate delay C_SGDLY and the current net delay C_NDLY that are computed in the above process (S350) may be used or may be recalculated after the sizes of all SCGs are optimized. The addition of the dummy loads may be checked with respect to all of the SCGs and the dummy loads may be unnecessary with respect to some SCGs. In an exemplary embodiment, the addition of the dummy loads may be omitted.

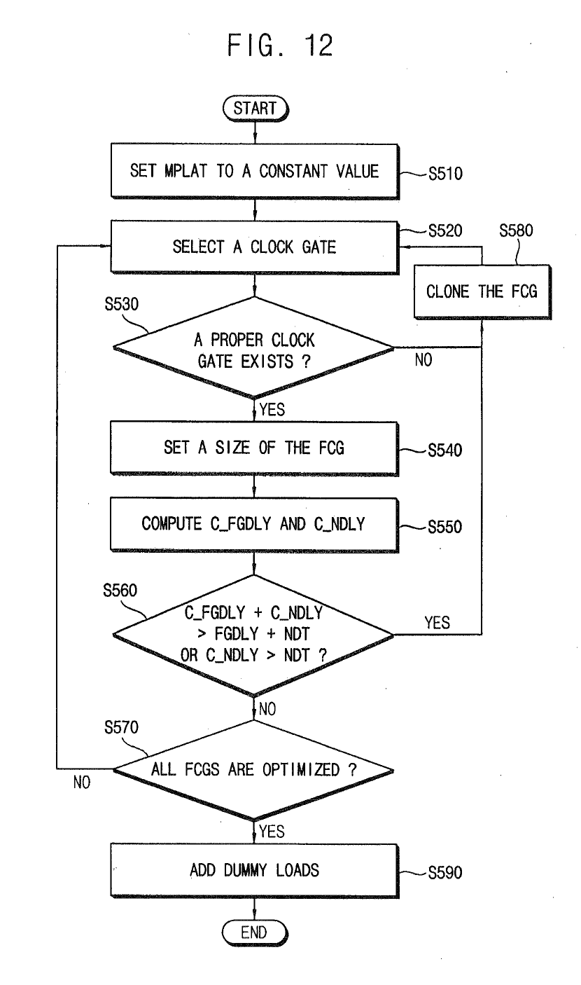

FIG. 11 is a diagram illustrating a placement design of an integrated circuit after the process of FIG. 10 is performed.

Referring to FIGS. 6, 10 and 11, the end-point cluster CA, which is driven by the SCG1 as shown in FIG. 6, is divided into the two end-point clusters CA1 and CA2, which are driven by the SCG11 and the SCG12, respectively, as shown in FIG. 11. The sizes of the SCG11 and the SCG12 are optimized such that the delays of the output clock signals may be aligned to the base latency BLAT.

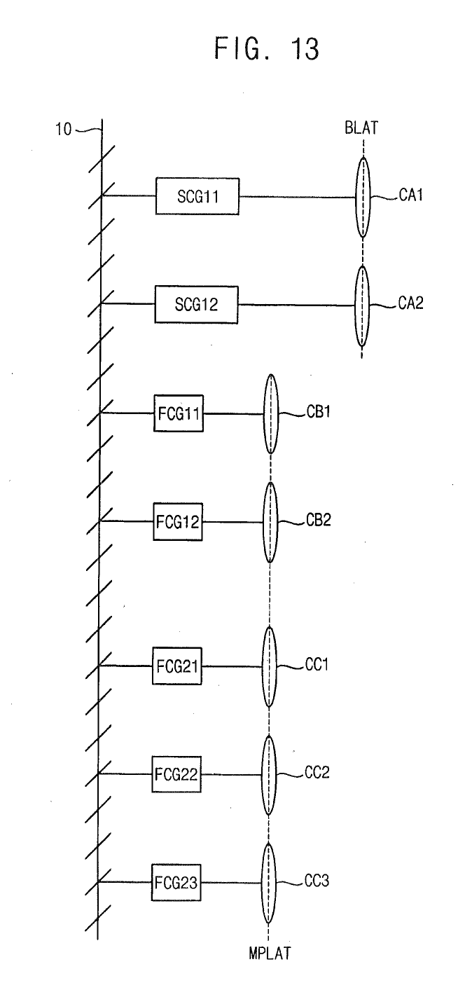

FIG. 12 is a flowchart illustrating an exemplary process of determining the fast clock gates included in the method of FIG. 1.

Referring to FIG. 12, the minimum pull latency MPLAT is set to a constant value (S510). As described above with reference to FIGS. 7, 8 and 9, the constant minimum pull latency MPLAT may be determined by setting the fast clock gate latency GLAT2, the fast clock gate delay FGDLY and the net delay threshold NDT2 to the constant values, respectively.

Based on the input transition and the driving load with respect to the one FCG, a clock gate is selected from the above-mentioned clock gate library (S520) such that the selected clock gate has a delay closest to the constant fast clock gate delay FGDLY.

When the clock gate library includes the clock gate having the delay closest to the constant fast clock gate delay FGDLY with respect to the one FCG (S530: YES), a size of the one FCG is set to a size of the selected clock gate (S540).

When the clock gate library does not include the clock gate having the delay closest to the constant fast clock gate delay FGDLY with respect to the one SCG (S530: NO), the one FCG is cloned into the two or more FCGs (S580). The cloning process may be performed by dividing the EPCs driven by the one FCG into two or more groups and then disposing the two or more FCGs, which replace the one FCG, to drive the two or more groups, respectively. The size optimizing processes (S520, S530 and S540) may be repeated with respect to each of the cloned FCGs.

With respect to the one size-set FCG, a current fast clock gate delay C_FGDLY and a current net delay C_NDLY are computed (S540).

When a sum C_FGDLY+C_NDLY of the current fast clock gate delay C_FGDLY and the current net delay C_NDLY is greater than a sum FGDLY+NDT of the constant fast clock gate delay FGDLY and the constant net delay threshold NDT or when the current net delay C_NDLY is greater than the constant net delay threshold NDT (S560: YES), the one FCG is cloned into the two or more FCGs (S580) as described above.

Until the size optimization is complete with respect to all FCGs (5370: NO), the above-described size-determining and cloning processes are repeated.

When the sizes optimization is complete with respect to all FCGs (S570: YES), dummy loads may be added to output nodes of the FCGs, respectively (S590). The respective dummy load may be added to an output node of the one size-set FCG such that the sum C_FGDLY+C_NDLY of the current fast clock gate delay C_FGDLY and the current net delay C_NDLY is equal or substantially equal to the sum FGDLY+NDT of the constant fast clock gate delay FGDLY and the constant net delay threshold NDT. The current fast clock gate delay C_FGDLY and the current net delay C_NDLY that are computed in the above process (S550) may be used or may be recalculated after the sizes of all FCGs are optimized. The addition of the dummy loads may be checked with respect to all of the FCGs and the dummy loads may be unnecessary with respect to some FCGs. In an exemplary embodiment, the addition of the dummy loads may be omitted.

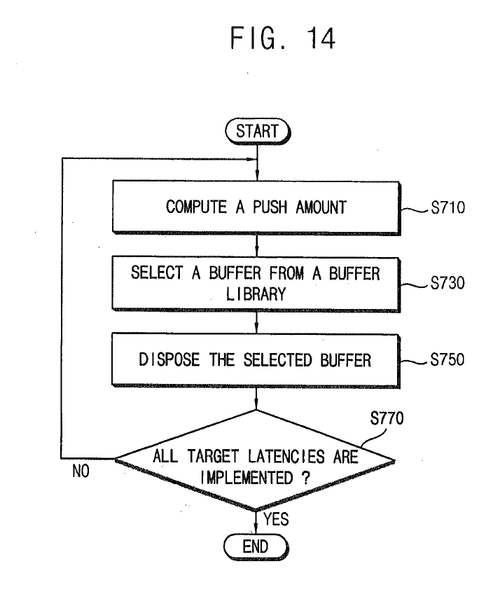

FIG. 13 is a diagram illustrating a placement design of an integrated circuit after the process of FIG. 12 is performed.

Referring to FIGS. 11, 12 and 13, the end-point cluster CB, which is driven by the FCG1 as shown in FIG. 11, is divided into the two end-point clusters CB1 and CB2, which are driven by the FCG11 and the FCG12, respectively, as shown in FIG. 12. The end-point cluster CC, which is driven by the FCG2 as shown in FIG. 11, is divided into three end-point clusters CC1, CC2 and CC3, which are driven respectively by the FCG21, FCG22 and the FCG23 as shown in FIG. 12. The sizes of the FCG11, the FCG12, the FCG21, the FCG22 and the FCG23 are optimized such that the delays of the output clock signals may be aligned to the minimum pull latency MPLAT.

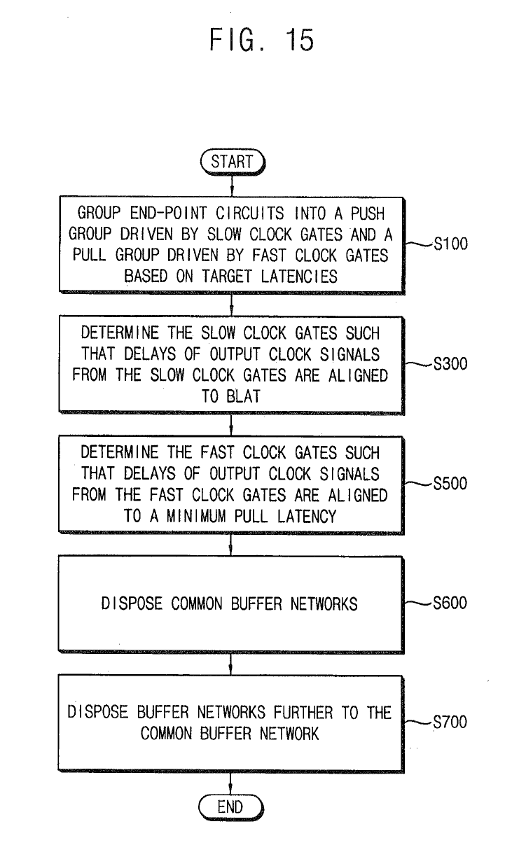

FIG. 14 is a flowchart illustrating an exemplary process of disposing the buffer networks included in the method of FIG. 1.

Referring to FIG. 14, the buffer networks may be disposed such that proper delay buffers are inserted between the clock gates and the corresponding end-point circuits with respect to all clock gates requiring push delays from the base latency BLAT or the minimum pull latency MPLAT.

With respect to one EPC driven by one SCG or one FCG, a push amount is computed (S710). The push amount corresponds to a difference between a corresponding target latency and the base latency BLAT or a difference between the corresponding target latency and the minimum pull latency.

A buffer is selected from the above-mentioned buffer library such that the selected buffer has a delay closest to the push amount (S730). The selected buffer is disposed between the one EPC and the one SCG or between the one EPC and the one FCG (S750). The buffer insertion may be omitted when the push amount is zero or is within a permitted small range.

Until all target latencies are implemented with respect to all EPCs (S770: NO), the above processes S710, S730, and S750 are repeated. When all target latencies are implemented with respect to all EPCs (S770: YES), the skew implementation method is completed, and the placement design as illustrated in FIG. 3 is provided.

Referring back to FIG. 3, the end-point cluster CA1 is driven by the slow clock gate SCG11 that is aligned to the base latency BLAT. The end-point circuits in the cluster CA1 may receive the local clock signals having the target latencies equal to the base latency BLAT, which corresponds to zero-skew.

The end-point clusters CB1, CB2, CC1 and CC3 are driven by the fast clock gates FCG11, FCG12, FCG21 and FCG23 that are aligned to the minimum pull latency MPLAT. The end-point circuits in the clusters CB1, CB2, CC1 and CC3 may receive the local clock signals having the target latencies equal or substantially equal to the minimum pull latency MPLAT, which is pulled to maximum amount from the base latency BLAT.

The end-point cluster CA2 is driven by the slow clock gate SCG12 that is aligned to the base latency BLAT, and the buffer network BNA2 is disposed between the end-point cluster CA2 and the slow clock gate SCG12. The end-point circuits in the cluster CA2 may receive the local clock signals having the target latencies greater than the base latency BLAT.

The end-point cluster CC2 is driven by the slow clock gate FCG22 that is aligned to the minimum pull latency MPLAT, and the buffer network BNC2 is disposed between the end-point cluster CC2 and the fast clock gate FCG22. The end-point circuits in the cluster CC2 may receive the local clock signals having the target latencies greater than the minimum pull latency MPLAT and smaller than the base latency BLAT.

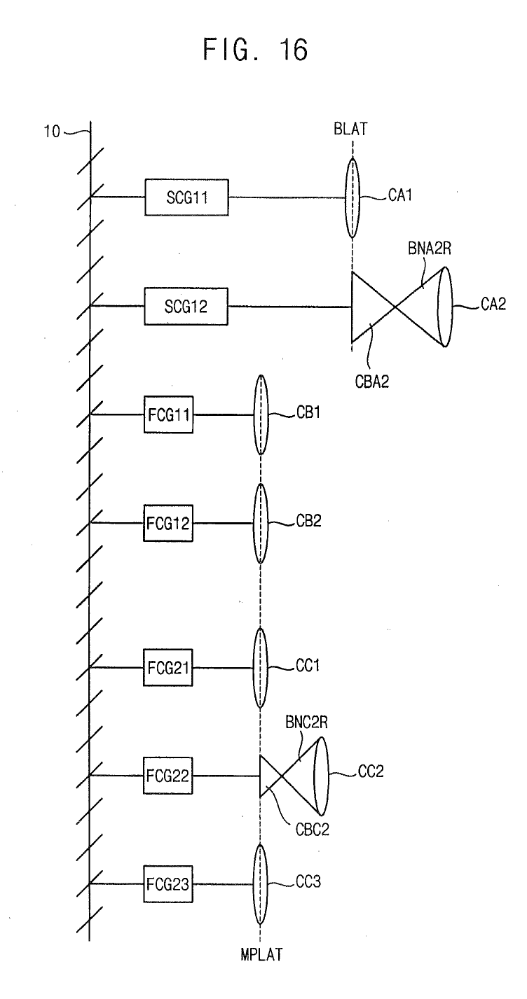

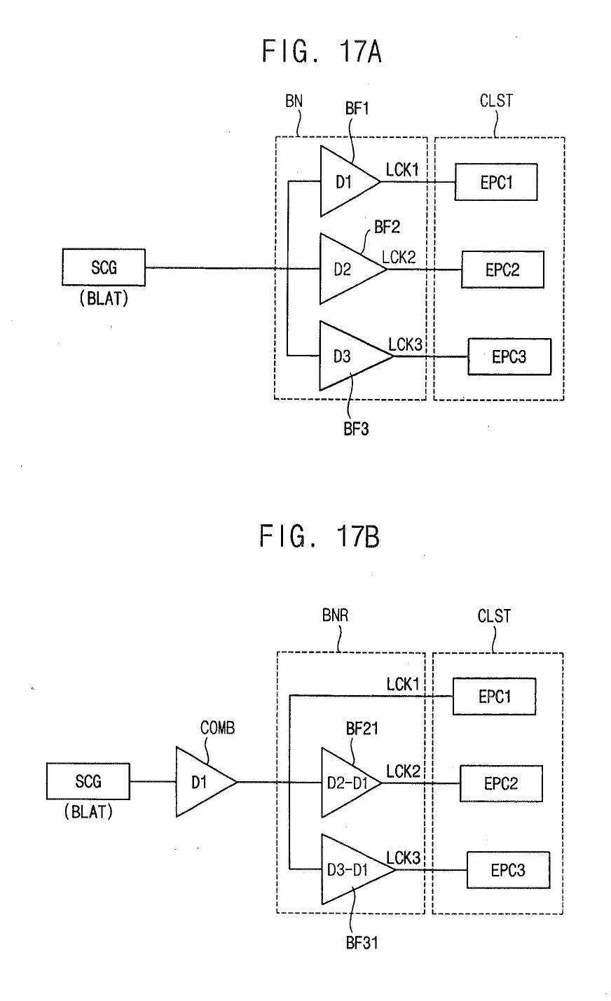

FIG. 15 is a flowchart illustrating a method of implementing clock skew in an integrated circuit according to an exemplary embodiment, and FIG. 16 is a diagram illustrating a placement design of an integrated circuit after the skew implementation method of FIG. 15 is applied.

Referring to FIG. 15, end-point circuits (EPCs) are grouped into a push group driven by one or more slow clock gates (SCGs) and a pull group driven by one or fast clock gates (FCGs) based on target latencies of local clock signals (S100).

After the EPCs are grouped, the SCGs are determined or optimized such that delays of output clock signals from the SCGs are aligned to the BLAT (S300), and the FCGs are determined or optimized such that delays of output clock signals from the FCGs are aligned to the MPLAT smaller than the BLAT (S500). The steps S100, S300 and S500 are substantially the same as the steps S100, S300, and S500 described above with reference to FIGS. 1 through 14.

After the SCGs and the FCGs are determined or optimized, common buffer networks are disposed (S600) and then the buffer networks are disposed further to the common buffer networks (S700). After the common buffer networks are disposed, the respective buffer networks are disposed between the common buffer networks and the EPCs.

The common buffer networks may be disposed as follows.

With respect to the EPCs driven by the one SCG or the one FCG, push amounts are computed such that the push amounts correspond to differences between the corresponding target latencies and the base latency BLAT or differences between the corresponding target latencies and the minimum pull latency MPLAT. A buffer is selected from the above-mentioned buffer library such that the selected buffer has a delay closest to a minimum push amount among the push amounts. The selected buffer is disposed on a common path between the EPCs and the one SCG or between the EPCs and the one FCG.

Compared with the placement design of FIG. 3, the placement design of FIG. 16 further includes the common buffer networks CBA2 and CBC2. By disposing the common buffer networks CBA2 and CBC2, the entire occupation area of the delay buffers for implementing the target latencies may be further reduced.

In an exemplary embodiment, instead of disposing the common buffer networks, the size of the already optimized clock gate may be changed as follows.

After determining or optimizing the sizes of the SCGs and the FCGs, with respect to the EPCs driven by the one SCG or the one FCG, push amounts are computed such that the push amounts correspond to differences between the corresponding target latencies and the base latency BLAT or differences between the corresponding target latencies and the minimum pull latency MPLAT. A clock gate is selected from the above-mentioned clock gate library such that the selected clock gate has a delay closest to a sum of a minimum push amount among the push amounts and the base latency BLAT or a sum of the minimum push amount and the minimum pull latency MPLAT. A size of the one SCG or the one FCG is changed and set to a size of the selected clock gate.

As such, the entire occupation area of the clock gates and the buffers may be reduced by re-optimizing the sizes of the clock gates.

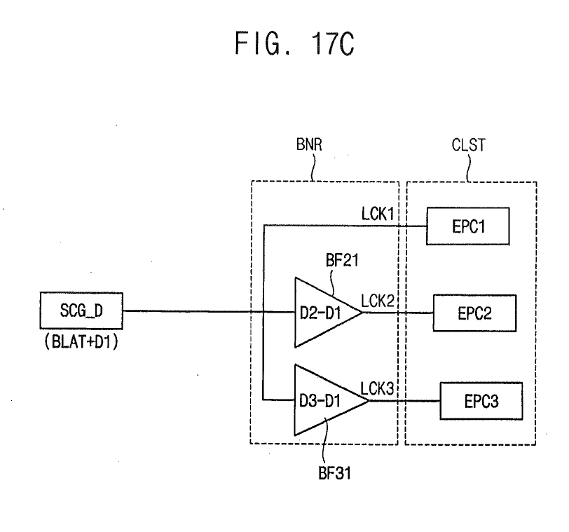

FIGS. 17A, 17B and 17C are diagrams illustrating clock transfer paths for describing methods of implementing clock skew according to exemplary embodiments.

FIG. 17A illustrates an exemplary clock transfer path where a buffer network BN is disposed between one SCG and an end-point cluster CLST. Even though the cluster CLST including three end-point circuits EPC1, EPC2 and EPC3 is illustrated in FIG. 17A, the number of EPCs in the cluster driven by the one clock gate may be changed.

The SCG may have an optimized size in which a delay of an output clock signal is aligned to the base latency BLAT as described with reference to FIGS. 10 and 11. The buffers BF1, BF2 and BF3 are disposed between the SCG and the end-point circuits EPC1, EPC2 and EPC3 so that the local clock signals LCK1, LCK2 and LCK3 may have the respective target latencies, as described above with reference to FIG. 14.

The delay amounts D1, D2 and D3 correspond to the above-mentioned push amounts. In the example of FIG. 17A, the target latency of the LCK1 applied to the EPC1 corresponds to BLAT+D1, the target latency of the LCK2 applied to the EPC2 corresponds to BLAT+D2, and the target latency of the LCK3 applied to the EPC3 corresponds to BLAT+D3.

For example, when the delay amount D1 of the first buffer BF1 corresponds to the minimum push amount, a common buffer COMB having the delay amount D1 may be disposed on a common path between the SCG and the end-point circuits EPC1, EPC2 and EPC3, as illustrated in FIG. 17B. The buffer network BNR as shown in FIG. 17B includes the buffers BF21 and BF31 having the reduced delay amounts D2−D1 and D3−D1 compared with the buffer network BN as shown in FIG. 17A. As such, the entire occupation area of the buffers may be reduced by disposing the common buffer COMB.

Referring to FIGS. 17B and 17C, the SCG having a size corresponding to BLAT and the common buffer COMB having the delay D1 as shown in FIG. 17B may be replaced with the SCG_D having a re-optimized size corresponding to BLAT+D1. The size of the clock gate may be re-optimized such that the delay of the output clock signal from the clock gate may be changed from BLAT to BLAT+D1. As such, the entire occupation area of the clock gates and the buffers may be reduced by re-optimizing the sizes of the clock gates.

Even though the clock transfer paths driven by the slow clock gate associated with the base latency BLAT, have been described with reference to FIGS. 17A, 17B and 17C, the same or similar description may be also applicable to clock transfer paths driven by the fast clock gate associated with the minimum pull latency MPLAT.

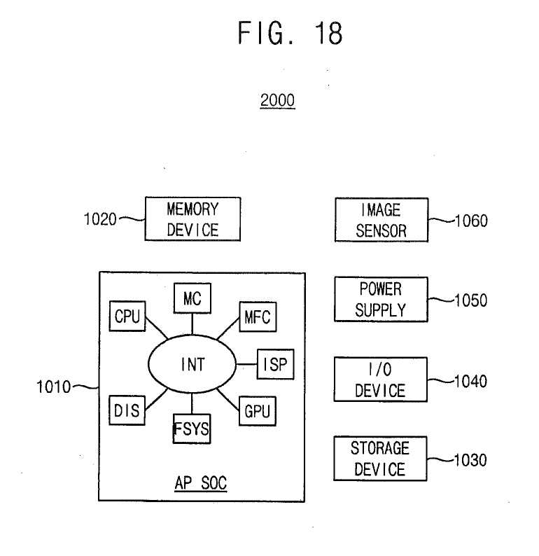

FIG. 18 is a block diagram illustrating a computing system according to an exemplary embodiment.

Referring to FIG. 18, a computing system 2000 includes a system on chip (SOC), a memory device 1020, a storage device 1030, an input/output (I/O) device 1040, a power supply 1050 and an image sensor 1060. According to an embodiment of the present invention, the computing system 2000 may further include ports that communicate with a video card, a sound card, a memory card, a USB device, or other electronic devices.

The SOC 1010 may be an application processor (AP) SOC including an interconnect device INT and a plurality of functional elements or functional devices coupled to the interconnect device INT. As illustrated in FIG. 18, the functional elements may include a memory controller MC, a central processing unit CPU, a display controller DIS, a file system block FSYS, a graphic processing unit GPU, an image signal processor ISP, and a multi-format codec block MFC. The SOC 1010 may be an integrated circuit to which the method of implementing clock skew as described with reference to FIGS. 1 through 17C is applicable. According to an exemplary embodiment, useful skew of the local clock signals may be implemented in each of the functional elements and/or between the functional elements.

The SOC 1010 may communicate with the memory device 1020, the storage device 1030, the input/output device 1040 and the image sensor 1060 via a bus, such as an address bus, a control bus, and/or a data bus. In an exemplary embodiment, the SOC 1010 is coupled to an extended bus, such as a peripheral component interconnection (PCI) bus.

The memory device 1020 may store data for operating the computing system 2000. For example, the memory device 1020 may include a dynamic random access memory (DRAM) device, a mobile DRAM device, a static random access memory (SRAM) device, a phase random access memory (PRAM) device, a ferroelectric random access memory (FRAM) device, a resistive random access memory (RRAM) device, and/or a magnetic random access memory (MRAM) device. The storage device 1030 may include a solid state drive (SSD), a hard disk drive (HDD), or a CD-ROM. The input/output device 1040 may include an input device (e.g., a keyboard, a keypad, a mouse, etc.) and an output device (e.g., a printer, a display device, etc.). The power supply 1050 supplies operation voltages to the computing system 2000.

The image sensor 1060 may communicate with the SOC 1010 via buses or other communication links. As described above, the image sensor 1060 may be integrated with the SOC 1010 in one chip, or the image sensor 1060 and the SOC 1010 may be implemented as separate chips, respectively.

The components in the computing system 2000 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

The computing system 2000 may be any computing system including at least one SOC. For example, the computing system 2000 may include a digital camera, a mobile phone, a smart phone, a portable multimedia player (PMP), a personal digital assistant (PDA), or a tablet computer.

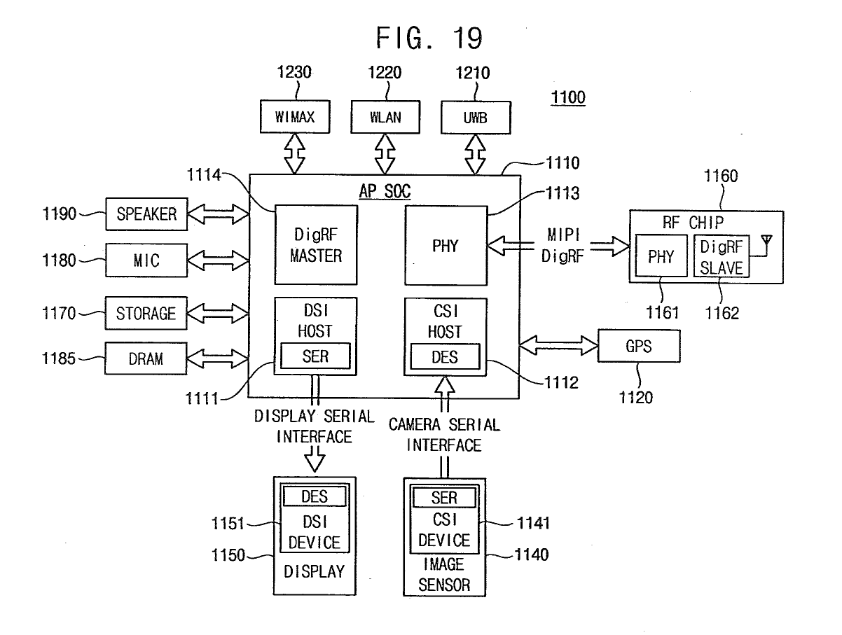

FIG. 19 is a block diagram illustrating an interface used in the computing system of FIG. 18 according to an exemplary embodiment.

Referring to FIG. 19, a computing system 1100 may be implemented as a data processing device that uses or supports a mobile industry processor interface (MIPI) interface. The computing system 1100 may include an AP (Application Processor)-type SOC 1110, an image sensor 1140, and a display device 1150. The SOC may include an interconnect device and service controllers as described above according to an exemplary embodiment.

A CSI host 1112 of the SOC 1110 may perform serial communication with a CSI device 1141 of the image sensor 1140 via a camera serial interface (CSI). In an exemplary embodiment of the present invention, the CSI host 1112 may include a deserializer (DES), and the CSI device 1141 may include a serializer (SER). A DSI host 1111 of the SOC 1110 may perform serial communication with a DSI device 1151 of the display device 1150 via a display serial interface (DSI).

In an exemplary embodiment of the present invention, the DSI host 1111 may include a serializer (SER), and the DSI device 1151 may include a deserializer (DES). The computing system 1100 may further include a radio frequency (RF) chip 1160 performing a communication with the SOC 1110. A physical layer (PHY) 1113 of the computing system 1100 and a physical layer (PHY) 1161 of the RF chip 1160 may perform data communication based on a MIPI DigRF. The SOC 1110 may further include a DigRF MASTER 1114 that controls the data communication of the physical layer PHY 1161.

The computing system 1100 may further include a global positioning system (GPS) 1120, a storage 1170, a microphone MIC 1180, DRAM device 1185, and/or a speaker 1190. The computing system 1100 may perform communication using an ultra wideband (UWB) 1210, a wireless local area network (WLAN) 1220, and/or a worldwide interoperability for microwave access (WIMAX) 1230. However, the structure and the interface of the system 11000 are not limited thereto.

A method of controlling a system according to an exemplary embodiment of the inventive concept may be efficiently used in arbitrary integrated circuits, such as application processors. At least one of the exemplary embodiments may be applicable to an SOC in which various semiconductor components are integrated as one chip. According to an exemplary embodiment of the inventive concept, a useful skew may be implemented in systems, such a digital camera, a mobile phone, a PDA, APMT, and/or a smart phone, with a smaller size, a higher performance and a higher operational speed.

The foregoing is illustrative of exemplary embodiments and is not to be construed as limiting to the present inventive concepts. Although a few exemplary embodiments have been described, those skilled in the art will readily appreciate that many modifications are possible in the exemplary embodiments without materially departing from the novel teachings and aspects of the present inventive concepts.

What is claimed is:

1. A method of implementing a clock skew in an integrated circuit, the method comprising:
grouping one or more end-point circuits into a push group and a pull group based on target latencies of local clock signals respectively driving the end-point circuits, wherein end-point circuits in the push group are configured to be driven by one or more slow clock gates, and end-point circuits in the pull group are configured to be driven by one or more fast clock gates;
determining one or more characteristics for the slow clock gates such that delays of output clock signals from the slow clock gates are aligned to a base latency;
determining one or more characteristics for the fast clock gates such that delays of output clock signals from the fast clock gates are aligned to a minimum pull latency smaller than the base latency; and
disposing one or more buffer networks between the fast and slow clock gates and the end-point circuits such that the local clock signals have the target latencies, respectively.

2. The method of claim 1, wherein grouping the end-point circuits includes:
establishing an initial placement design of the integrated circuit such that each of the end-point circuits are driven by the slow clock gates;
when a predetermined number of the end-point circuits driven by a first slow clock gate of the slow clock gates in the initial placement design are included in the pull group, separating the predetermined number of the end-point circuits from the first slow clock gate and disposing a first fast clock gate to drive the separated predetermined number of the end-point circuits; and
when all of the end-point circuits driven by the first slow clock gate in the initial placement design are included in the pull group, replacing the first slow clock gate with the first fast clock gates.

3. The method of claim 2, wherein grouping the end-point circuits further includes:
when the slow clock gates have the same input signal and are disposed adjacent to each other, merging the slow clock gates with each other; and
when the fast clock gates have the same input signal and are disposed adjacent to each other, merging the fast clock gates with each other.

4. The method of claim 1, wherein the base latency is a sum of a slow clock gate latency that occurs before a predetermined slow clock gate of the slow clock gates, a slow clock gate delay that occurs in the predetermined slow clock gate, and a first net delay threshold that is an upper limit of a delay that occurs from the predetermined slow clock gate to a predetermined end-point circuit of the end-point circuits, and
wherein the minimum pull latency is a sum of a fast clock gate latency that occurs before a predetermined fast clock gate of the fast clock gates, a fast clock gate delay that occurs in the predetermined fast clock gate, and a second net delay threshold that is an upper limit of a delay that occurs from the predetermined fast clock gate to another predetermined end-point circuit of the end-point circuits.

5. The method of claim 4, wherein the slow clock gate latency and the fast clock gate latency are set to constant values by driving the slow and fast clock gates using a clock distribution network including a clock mesh, and wherein the slow clock gate delay, the fast clock gate delay and the first and second net delay thresholds are set to constant values based on an entire occupation area of the slow and fast clock gates.

6. The method of claim 5, wherein determining one or more characteristics for the slow clock gates includes:
based on an input transition and a driving load of the first slow clock gate, selecting a clock gate from a clock gate library such that the selected clock gate has a delay closest to the constant value of the slow clock gate delay; and
setting a size of the first slow clock gate to a size of the selected clock gate.

7. The method of claim 6, wherein determining one or more characteristics for the slow clock gates further includes:
when the clock gate library does not include the clock gate having the delay closest to the constant value of the slow clock gate delay with respect to the first slow clock gate, dividing the end-point circuits driven by the first slow clock gate into two or more groups; and
replacing the first slow clock gate with two or more other slow clock gates configured to respectively drive the two or more groups of the end-point circuits.

8. The method of claim 6, wherein determining one or more characteristics for the slow clock gates further includes:
computing a current slow clock gate delay and a current net delay with respect to the first slow clock gate;
when a sum of the current slow clock gate delay and the current net delay is greater than a sum of the constant value of the slow clock gate delay and the constant value of the net delay threshold or when the current net delay is greater than the constant value of the net delay threshold, dividing the end-point circuits driven by the first slow clock gate into two or more groups; and
replacing the first slow clock gate with two or more other slow clock gates configured to respectively drive the two or more groups of the end-point circuits.

9. The method of claim 6, wherein determining one or more characteristics for the slow clock gates further includes:
computing a current slow clock gate delay and a current net delay with respect to the first slow clock gate; and
adding a dummy load to an output node of the first slow clock gate such that a sum of the current slow clock gate delay and the current net delay is equal or substantially equal to a sum of the constant value of the slow clock gate delay and the constant value of the net delay threshold.

10. The method of claim 5, wherein determining one or more characteristics for the fast clock gates includes:
based on an input transition and a driving load of the first fast clock gate, selecting a clock gate from a clock gate library such that the selected clock gate has a delay closest to the constant value of the fast clock gate delay; and
setting a size of the first fast clock gate to a size of the selected clock gate.

11. The method of claim 10, wherein determining one or more characteristics for the fast clock gates further includes:
when the clock gate library does not include the clock gate having the delay closest to the constant value of the fast clock gate delay with respect to the first fast clock gate, dividing the end-point circuits driven by the first fast clock gate into two or more groups; and
replacing the first fast clock gate with two or more other fast clock gates configured to respectively drive the two or more groups of the end-point circuits.

12. The method of claim 10, wherein determining one or more characteristics for the fast clock gates further includes:
computing a current fast clock gate delay and a current net delay with respect to the first fast clock gate;
when a sum of the current fast clock gate delay and the current net delay is greater than a sum of the constant value of the fast clock gate delay and the constant value of the net delay threshold or when the current net delay is greater than the constant value of the net delay threshold, dividing the end-point circuits driven by the first fast clock gate into two or more groups; and
replacing the first fast clock gate with two or more other fast clock gates configured to respectively drive the two or more groups of the end-point circuits.

13. The method of claim 10, wherein determining one or more characteristics for the fast clock gates further includes:
computing a current fast clock gate delay and a current net delay with respect to the first fast clock gate; and
adding a dummy load to an output node of the first fast clock gate such that a sum of the current fast clock gate delay and the current net delay is equal or substantially equal to a sum of the constant value of the fast clock gate delay and the constant value of the net delay threshold.

14. The method of claim 1, wherein disposing the buffer networks includes:
with respect to one of the end-point circuits driven by one of the slow clock gates or one of the fast clock gates, computing a push amount corresponding to a difference between a corresponding target latency of the target latencies and the base latency or a difference between the corresponding target latency and the minimum pull latency;
selecting a buffer from a buffer library such that the selected buffer has a delay closest to the push amount; and
disposing the selected buffer between the one end-point circuit and the one slow clock gate or between the one end-point circuit and the one fast slow clock gate.

15. The method of claim 1, further comprising:
after determining one or more characteristics for the slow clock gates and the fast clock gates, with respect to the end-point circuits driven by one of the slow clock gates or one of the fast clock gates, computing push amounts corresponding to differences between corresponding target latencies of the target latencies and the base latency or differences between the corresponding target latencies and the minimum pull latency;
selecting a buffer from a buffer library such that the selected buffer has a delay closest to a minimum push amount of the push amounts; and
disposing the selected buffer on a common path between the end-point circuits and the one slow clock gate or between the end-point circuits and the one fast slow clock gate.

16. The method of claim 1, further comprising:
after determining one or more characteristics for the slow clock gates and the fast clock gates, with respect to the end-point circuits driven by one of the slow clock gates or one of the fast clock gates, computing push amounts corresponding to differences between corresponding target latencies of the target latencies and the base latency or differences between the corresponding target latencies and the minimum pull latency;
selecting a clock gate from a clock gate library such that the selected clock gate has a delay closest to a sum of a minimum push amount of the push amounts and the base latency or a sum of the minimum push amount and the minimum pull latency; and
setting a size of the one slow clock gate or the one fast clock gate to a size of the selected clock gate.

17. An integrated circuit comprising:
a clock distribution network including a clock mesh configured to provide one or distributed clock signals;
one or more slow clock gates configured to receive the distributed clock signals and to output clock signals having delays aligned to a base latency;
one or more fast clock gates configured to receive the distributed clock signals and to output clock signals having delays aligned to a minimum pull latency smaller than the base latency;
one or more buffer networks configured to delay the clock signals from the slow clock gates and the fast clock gates and to provide local clock signals having target latencies, respectively; and
end-point circuits configured to receive the local clock signals, respectively, from the slow clock gates, the fast clock gates or the buffer networks.

18. A method of implementing a clock skew in an integrated circuit, the method comprising:
providing a basic placement design for the integrated circuit, wherein the basic placement design includes a list of end-point circuits, a library of clock gates, and a library of buffers;
establishing a clock distribution network based on the basic placement design to provide an initial placement design, wherein the clock distribution network is connected to the end-point circuits via the clock gates;
performing skew scheduling on the basic placement design to provide target latencies of local clock signals from the clock gates; and
implementing the clock skew by disposing at least one of the buffers between the clock gates and the end-point circuits based on the initial placement design and the target latencies.

19. The method of claim 18, further comprising correcting the basic placement design or the clock distribution network based on information generated when the clock skew is implemented.

20. The method of claim 18, wherein the clock gates include a slow clock gate and a fast clock gate, and wherein a delay of an output clock signal from the slow clock gate is aligned to a base latency, and a delay of an output clock signal of from the fast clock gate is aligned to a minimum pull latency smaller than the base latency.
